(19) United States
(12) Patent Application Publication
(10) Pub. No.: US 2026/0123027 A1
(43) Pub. Date: Apr. 30, 2026

(54) APPARATUS WITH INTEGRATED PLANAR MOSFET AND INTEGRATED PLANAR SCHOTTKY BARRIER DIODE

(71) Applicant: Microchip Technology Incorporated, Chandler, AZ (US)

(72) Inventors: Shesh Mani Pandey, Gilbert, AZ (US); Dennis Meyer, Chandler, AZ (US); Bruce Odekirk, Portland, OR (US)

(73) Assignee: Microchip Technology Incorporated, Chandler, AZ (US)

(21) Appl. No.: 19/055,397

(22) Filed: Feb. 17, 2025

Related U.S. Application Data
(60) Provisional application No. 63/711,845, filed on Oct. 25, 2024.

(51) Int. Cl. H10D 84/00; H10D 62/832; H10D 84/01

(52) U.S. Cl. CPC H10D 84/146; H10D 62/8325; H10D 84/0105

(57) ABSTRACT

An apparatus including a planar metal oxide semiconductor field-effect transistor and a planar Schottky barrier diode that are physically and functionally integrated into a single, continuous structure, and a method of making such an apparatus. The planar Schottky barrier diode is located over a junction field-effect transistor neck region which is adjacent to the planar metal oxide semiconductor field-effect transistor in a single, continuous volume of semiconductor material. The planar metal oxide semiconductor field-effect transistor may include first and second transistor sides spaced apart at respective first and second sides of the volume of semiconductor material, in which case the junction field-effect transistor neck region and the planar Schottky barrier diode are located between the first and second transistor sides.

### RELATED APPLICATION

The present U.S. non-provisional patent application is related to and claims priority benefit of an earlier-filed U.S. provisional patent application titled “Apparatus Including Integrated Planar MOSFET and Schottky Barrier Diode,” Ser. No. 63/711,845, filed Oct. 25, 2024. The entire content of the identified earlier-filed application is incorporated by reference as if fully set forth herein.

### FIELD

The present disclosure relates to metal oxide semiconductor field-effect transistors and methods of making them, and more particularly, the various examples described herein concern an apparatus including an integrated planar metal oxide semiconductor field-effect transistor and an integrated planar Schottky barrier diode, and a method of making an apparatus including an integrated planar metal oxide semiconductor field-effect transistor and an integrated planar Schottky barrier diode.

### BACKGROUND

A metal oxide semiconductor field-effect transistor (MOSFET) is an active, voltage-controlled semiconductor device, in which varying an electrical voltage between a gate and a body controls an electrical current flowing through a semiconductor channel between a drain and a source. Applications for MOSFETs include amplifiers, switches, resistors, regulators, oscillators, and choppers. It is generally desirable to improve the performance and reduce the cost of MOSFETs, but it can be difficult to do so.

This background discussion is intended to provide related information, and is not necessarily prior art.

### SUMMARY

Examples provide an apparatus including an integrated planar MOSFET and an integrated planar Schottky barrier diode (SBD), and a method of making an apparatus including an integrated planar MOSFET and an integrated planar SBD. Broadly, the integrated SBD may be located over a JFET neck region which is adjacent to a gate component and between first and second sides of the integrated MOSFET, such that the MOSFET and the SBD are fully physically and functionally integrated into the apparatus, and are not discrete devices connected together. Examples advantageously improve reverse conduction by avoiding bipolar degradation when the parasitic P-N body diode is opened, and advantageously provide a much lower gate-drain capacitance (Cgd) while using less space, lowering switching losses, lowering cost, and requiring fewer dies in the manufacturing process.

In an example, an apparatus may include a volume of semiconductor material, an integrated planar MOSFET, a JFET neck region, and an integrated planar SBD. The volume of semiconductor material may include a first end, a second end, a first side, and a second side. The integrated planar MOSFET may include a first transistor side located at the first side of the volume of semiconductor material. The first transistor side may include a first Pwell located at the first end of the volume of semiconductor material, and a first gate. The first gate may include a first layer of dielectric material over at least a portion of the first P-well, and a first layer of doped polysilicon over the first layer of dielectric material. The JFET neck region of the volume of semiconductor material may be located adjacent to the first transistor side. The integrated planar SBD may include a Schottky material located at the first end of the volume of semiconductor material over at least a portion of the JFET neck region adjacent to and spaced apart from the first transistor side.

The preceding example may further include any one or more of the following features. The first transistor side may further include a first source including a first N+ material located above and adjacent to the first P-well, a first body including a first P+ material located adjacent to the first source opposite the first P-well, a first drain including an N+ substrate material located at the second end of the volume of semiconductor material, and a first channel through the volume of semiconductor between the first source and the first drain. The first layer of dielectric material may extend over at least a portion of the first source and a first portion of the JFET neck region. The integrated planar MOSFET may further include a second transistor side located at the second side of the volume of semiconductor material, wherein the JFET neck region may be located between the first and second transistor sides. The second transistor side may include a second Pwell located at the first end of the volume of semiconductor material, and a second gate. The second gate may include a second layer of dielectric material located over at least a portion of the second P-well, and a second layer of doped polysilicon over the second layer of dielectric material. The second transistor side may further include a second source including a second N+ material located above and adjacent to the second P-well, a second body including a second P+ material located adjacent to the second source opposite the second P-well, a second drain including an N+ substrate material located at the second end of the volume of semiconductor material, and a second channel through the volume of semiconductor between the second source and the second drain. The second layer of dielectric material may extend over at least a portion of the second source and a second portion of the junction field-effect transistor neck region. The Schottky material may be titanium, molybdenum, platinum, chromium, tungsten, aluminum, or combinations thereof.

In another example, an apparatus may include a volume of semiconductor material, an integrated planar MOSFET, a JFET neck region, and an integrated planar SBD. The volume of semiconductor material may include a first end, a second end, a first side, and a second side. The integrated planar MOSFET may include a first transistor side located at the first side of the volume of semiconductor material. The first transistor side may include a first well located at the first end of the volume of semiconductor material and a first gate. The integrated planar MOSFET may further include a second transistor side located at the second side of the volume of semiconductor material. The second transistor side may include a second well located at the first end of the volume of semiconductor material and a second gate. The JFET neck region of the volume of semiconductor material may be located between the first transistor side and the second transistor side. The integrated planar SBD may include a Schottky material located at the first end of the volume of semiconductor material over at least a portion of the JFET neck region between and spaced apart from the first and second transistor sides.

The preceding example may further include any one or more of the following features. The first gate may include a first layer of dielectric material over at least a portion of the first well, and a first layer of doped polysilicon over the first layer of dielectric material. The second gate may similarly include a second layer of dielectric material over at least a portion of the second well, and a second layer of doped polysilicon over the second layer of dielectric material. The first well may be formed of a P material. The first transistor side may further include a first source including a first N+ material located above and adjacent to the first P-well, a first body including a first P+ material located adjacent to the first source opposite the first P-well, a first drain including an N+ substrate material located at the second end of the volume of semiconductor material, and a first channel through the volume of semiconductor between the first source and the first drain. The second well may be formed of a P material. The second transistor side may further include a second source including a second N+ material located above and adjacent to the second P-well, a second body including a second P+ material located adjacent to the second source opposite the second P-well, a second drain including the N+ substrate material located at the second end of the volume of semiconductor material, and a second channel through the volume of semiconductor between the second source and the second drain. The first layer of dielectric material may extend over at least a portion of the first source and a first portion of the JFET neck region, and the second layer of dielectric material may extend over at least a portion of the second source and a second portion of the JFET neck region. The Schottky material may be a metal such as titanium, molybdenum, platinum, chromium, tungsten, aluminum, or combinations thereof.

In another example, a method may include the following operations. A volume of semiconductor material may be grown including a first end, a second end, a first side, and a second side, and including a junction field effect transistor neck region. A first transistor side of an integrated planar MOSFET may be formed at the first side of the volume of semiconductor material and adjacent to the JFET neck region. Formation of the first transistor side may include implanting a first P-well at the first end of the volume of semiconductor material and forming a first gate. Formation of the first gate may include depositing a first layer of dielectric material over at least a portion of the first P-well, and depositing a first layer of doped polysilicon over the first layer of dielectric material. An integrated planar SBD may be made including adding a Schottky material at the first end of the volume of semiconductor material over at least a portion of the JFET neck region adjacent and spaced apart from the first transistor side.

The preceding example may further include any one or more of the following features. Making the first transistor side may further include implanting a first N+ material for a first source above and adjacent to the first P-well, implanting a first P+ material for a first body adjacent to the first source opposite the first P-well, and providing an N+ substrate material for a first drain at the second end of the volume of semiconductor material, wherein the volume of semiconductor between the first source and the first drain provides a first channel. The first layer of dielectric material may extend over at least a portion of the first source and a first portion of the JFET neck region. The method may further comprise forming a second transistor side of the integrated planar MOSFET at the second side of the volume of semiconductor material. Formation of the second transistor side may include implanting a second P-well at the first end of the volume of semiconductor material and forming a second gate. Formation of the second gate may include depositing a second layer of dielectric material over at least a portion of the second P-well, and depositing a second layer of doped polysilicon over the second layer of dielectric material. Formation of the second transistor side may further include implanting a second N+ material for a second source above and adjacent to the second P-well, and implanting a second P+ material for a second body adjacent to the second source opposite the second P-well, wherein the N+ substrate material provides a second drain at the second end of the volume of semiconductor material, and wherein the volume of semiconductor between the first source and the first drain provides a second channel. The second layer of dielectric material may extend over at least a portion of the second source and a second portion of the JFET neck region. The Schottky material may be titanium, molybdenum, platinum, chromium, tungsten, aluminum, or combinations thereof.

This summary is not intended to identify essential features of the examples, and is not intended to be used to limit the scope of the claims. These and other aspects of the present examples are described below in greater detail.

### DRAWINGS

Examples are described in detail below with reference to the attached drawing figures, wherein:

FIG. 1 is a cross-sectional elevation view of an example of an apparatus including an integrated planar MOSFET and an integrated planar SBD, wherein the integrated SBD is shown located between first and second sides of the integrated planar MOSFET;

FIG. 2 is a flowchart of operations in an example of a method of making an apparatus including an integrated planar MOSFET and an integrated planar SBD, wherein the integrated SBD is located between first and second sides of the integrated planar MOSFET;

FIG. 3A is a cross-sectional elevation view of the result of an operation in the method of FIG. 2, wherein a volume of N-type epitaxial semiconductor material is shown on an N+ drain substrate material, and an N+ source material and a P+ body material are implanted in the volume of semiconductor material;

FIG. 3B is a cross-sectional elevation view of the result of an operation in the method of FIG. 2, wherein a dielectric material, or gate oxide, is grown and a polysilicon gate material is deposited and etched; and

FIG. 3C is a cross-sectional elevation view of the result of an operation in the method of FIG. 2, wherein a Schottky material is provided and electrical terminals are added.

The figures are not intended to limit the examples to the specific details depict. The drawings are not necessarily to scale.

### DETAILED DESCRIPTION

In the following detailed description, reference is made to the accompanying drawings, which form a part hereof and in which are shown, by way of illustration, specific examples in which the present disclosure may be practiced. These examples are described in sufficient detail to enable a person of ordinary skill in the art to practice the present disclosure. However, other examples may be utilized, and structural, material, procedural, operational, and other changes may be made without departing from the scope of the disclosure. Unless clearly understood or expressly identified otherwise, structures, materials, procedures, operations, and other aspects described in the context of one example may be incorporated into other examples.

The illustrations presented herein are not meant to be actual views of any particular method, system, device, or structure, but are merely idealized representations that are employed to describe the examples of the present disclosure. The drawings presented herein are not necessarily drawn to scale. Similar structures or components in the various drawings may retain the same or similar numbering for the convenience of the reader; however, any similarity in numbering does not necessarily mean that the structures or components are necessarily identical in size, composition, configuration, or any other property.

Terms of relative location and direction (e.g., above, below, left, right, upper, lower, vertical, horizontal (or lateral)) may be used to facilitate the present descriptions of examples with reference to the figures, but unless clearly understood or expressly identified otherwise, these terms are not meant to be limiting with regard to location, direction, or overall orientation, and may, for example, change as a result of a change in overall orientation.

Thus, it will be readily understood that the components of the examples as generally described herein and illustrated in the drawings could be arranged and designed in a wide variety of different configurations. Thus, the following description of various examples is not intended to limit the scope of the present disclosure but is merely representative of various examples.

Examples provide an apparatus including an integrated planar MOSFET and an integrated planar SBD, and a method of making an apparatus including an integrated planar MOSFET and an integrated planar SBD. Broadly, the integrated SBD may be located over a JFET neck region which is adjacent to a gate component and between first and second sides of the integrated MOSFET, such that the MOSFET and the SBD are fully physically and functionally integrated into the apparatus, and are not discrete devices connected together.

The improved reverse conduction (i.e., the third quadrant performance) of a SiC MOSFET is desirable for next-generation compact power electronics. Integration of the SBD with the MOSFET provides an efficient mechanism for avoiding bipolar degradation when the parasitic P-N body diode is opened. If the forward voltage of the body diode of the MOSFET is three and one-half (3.5) volts (V), and the forward voltage of the SBD is one and one-half (1.5) V, then the forward voltage drop is reduced by two (2) V, resulting in lower forward voltage losses. Further, integrating the SBD in this manner provides a much lower Cgd. Additionally, integrating the SBD rather than connecting a discrete SBD provides the advantages of using less space, lowering switching losses, lowering cost, and requiring fewer dies in the manufacturing process.

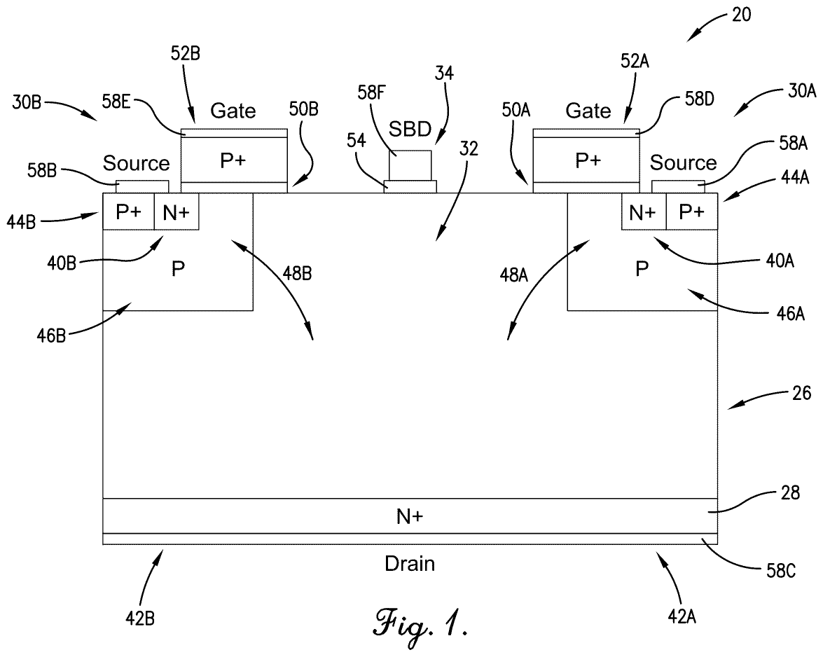

Referring to FIG. 1, an example of an apparatus 20 with an integrated planar MOSFET 30 and an integrated planar SBD 34 is shown. Broadly, the apparatus 20 may include a volume of semiconductor material 26, a doped substrate material 28, the integrated planar MOSFET 30, a JFET neck region 32, and the integrated planar SBD 34. The volume of semiconductor material 26 may include a first end, a second end, a first side, and a second side. The volume of semiconductor material 26 may be constructed from or include an N-type epitaxial semiconductor material. The doped substrate material 28 may be located at the second end of the volume of semiconductor material 26, and may be constructed from or include an N+ substrate material. The integrated planar MOSFET 30 may include a first MOSFET or transistor side 30A located at the first side of the volume of semiconductor material 26 and a second MOSFET or transistor side 30B located at the second side of the volume of semiconductor material 26. The JFET neck region 32 may be a region of the volume of semiconductor material 26 located between the first and second MOSFET sides 30A, 30B. More specifically, the integrated SBD 34 may be located at the first end of the volume of semiconductor material 26 over at least a portion of the JFET neck region 32 adjacent to and spaced apart from the first and second MOSFET sides 30A, 30B.

The integrated MOSFET 30 may be a silicon carbide (SIC) MOSFET. The first and second MOSFET sides 30A, 30B may include respective first and second regions or subvolumes of the volume of semiconductor material 26. Thus, the volume of semiconductor material 26 may be a single, physically continuous structure that is shared by the first and second MOSFET sides 30A, 30B and the integrated SBD 34. The first and second MOSFET sides 30A, 30B may further include respective first and second portions of the doped substrate material 28. Thus, the doped substrate material 28 may be a single, physically continuous structure that is shared by the first and second MOSFET sides 30A, 30B and the integrated SBD. The first and second MOSFET sides 30A, 30B may further include respective first and second instances of various structures and associated materials. Generally, the first and second MOSFET sides 30A, 30B may be mirror-images or “flipped” versions (i.e., flipped horizontally about the JFET neck region 32) of each other—i.e., some or all of the respective structures and associated materials may be reversed in order or position on opposite sides of the shared JFET neck region 32. The first and second MOSFET sides 30A, 30B may otherwise be substantially similar or identical. According to some aspects of the example apparatus, some structural variations between the transistor sides 30A, 30B may be permissible.

The first and second instances of the various structures and materials of the first and second MOSFET sides 30A, 30B may be implanted (using, e.g., an ion implanter), deposited, or otherwise provided using a suitable technique in or on the respective subvolumes of the volume semiconductor material 26. These structures and materials and their sizes and positions may vary, but may generally include the following. First and second sources 40A, 40B may be constructed from or include an N+ material, and may be located at the first end of the respective subvolumes of volume of semiconductor material 26 and generally opposite first and second drains 42A, 42B provided by respective portions of the N+ substrate 28. First and second body contacts 44A, 44B may be constructed from or including a P+ material, and may be located adjacent to the respective first and second sources 40A, 40B. First and second P-wells 46A, 46B may be constructed from or include a P+ material, and may be located below and adjacent to the respective first and second sources 40A, 40B, with each Pwell 46A, 46B being located an opposite side of the respective source 40A, 40B from the respective body contacts 44A, 44B. First and second channels 48A, 48B may be provided by respective first and second regions of the respective subvolumes of the volume of semiconductor material 26 between the respective first and second sources 40A, 40B and the respective first and second drains 42A, 42B. The majority charge carriers may move and the electrical current may flow through the channels 48A 48B.

First and second layers of dielectric material 50A, 50B, or gate oxide (e.g., silicon oxide (SiO₂)), may be provided over a portion of respective sides of the JFET neck region 32, at least partially over the respective first and second P-wells 46A, 46B, and at least partially over the respective first and second sources 40A, 40B. As seen in FIG. 1, no dielectric material is provided over a center portion of the JFET neck region 32 between the first and second MOSFET sides 30A, 30B. First and second of structures of a doped polysilicon material may be located over the respective first and second layers of dielectric material 50A, 50B. The doped polysilicon may be constructed from or include a P-type or N-type polysilicon material. The layers of dielectric material 50A, 50B and structures of doped polysilicon material cooperatively form respective first and second gates 52A, 52B, each corresponding with one of the MOSFET sides 30A, 30B. Alternative gate constructions may be within the ambit of the example apparatus. As seen in FIG. 1, the example MOSFET includes no polysilicon or oxide over the center portion of the JFET neck region 32 between the first and second MOSFET sides 30A, 30B. Thus, the first and second gates 52A, 52B may be located on either side of the JFET neck region 32 (providing a so-called “split gate design).

It will be appreciated that the example MOSFET is an N-channel MOSFET. However, certain aspects of the example MOSFET might be applicable to P-channel MOSFETs.

The integrated SBD 34 may be located over the center portion of the JFET neck region 32 between the first and second MOSFET sides 30A, 30B, and may include a Schottky material 54. The Schottky material 54 may be a metal such as titanium, molybdenum, platinum, chromium, tungsten, aluminum, or combinations thereof.

The apparatus 20 may further include electrical terminals 58A-F to facilitate applying appropriate electrical voltages, which are discussed below. More specifically, first and second electrical terminals 58A, 58B, may be added to the respective first and second sources 40A, 40B, a single third electrical terminal 58C may be added that spans the first and second drains 42A, 42B, fourth and fifth electrical terminals 58D, 58E may be added to the respective first and second gates 52A, 52B, and a sixth electrical terminal 58F may be added to the integrated SBD 34.

In operation, when a voltage, Vgs, is applied between the source 40A, 40B and the gate 52A, 52B, the generated electric field creates an inversion layer at the semiconductor-dielectric interface. The inversion layer provides the channel 48A, 48B through which electrical current can flow when another voltage, Vds, is applied between the source 40A, 40B and the drain 42A, 42B. More specifically, Vgs controls the width of the depletion region at the P-N junction where the charge carriers of the P- and N-type materials diffuse into each other, which “depletes” the available concentrations of majority charge carrier in each material, and thereby controls the current, Id, from the drain 42A, 42B to the source 40A, 40B. In the present examples, the integrated SBD 34 improves reverse conduction by avoiding bipolar degradation when the parasitic P-N body diode is opened, and provides a much lower Cgd.

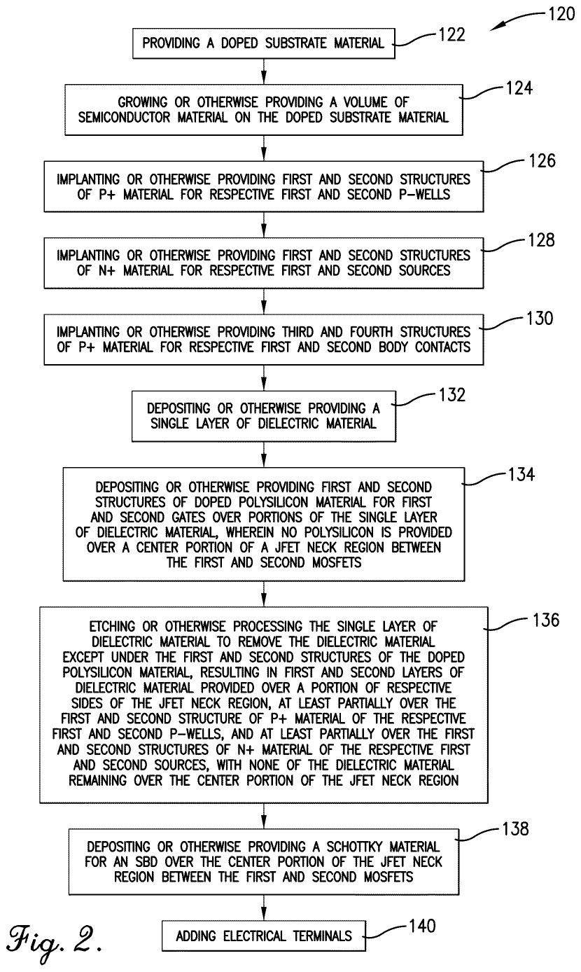

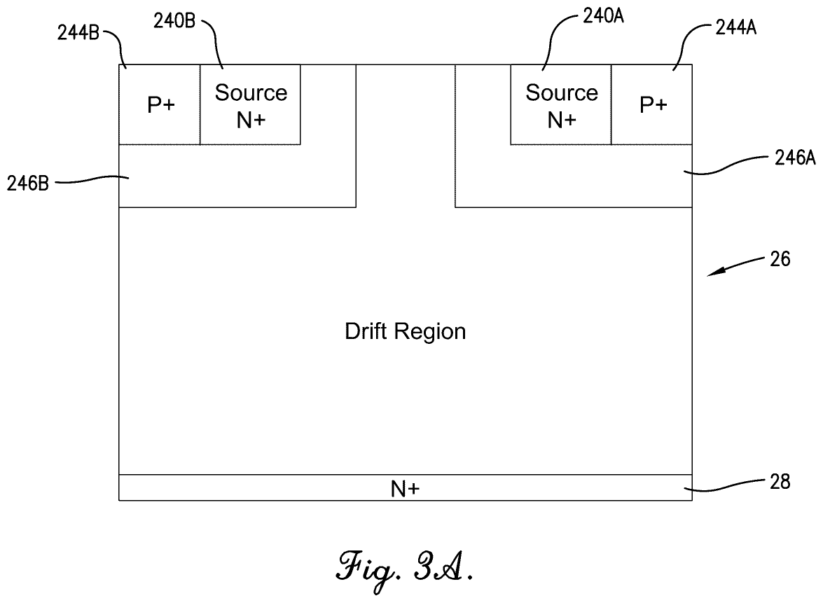

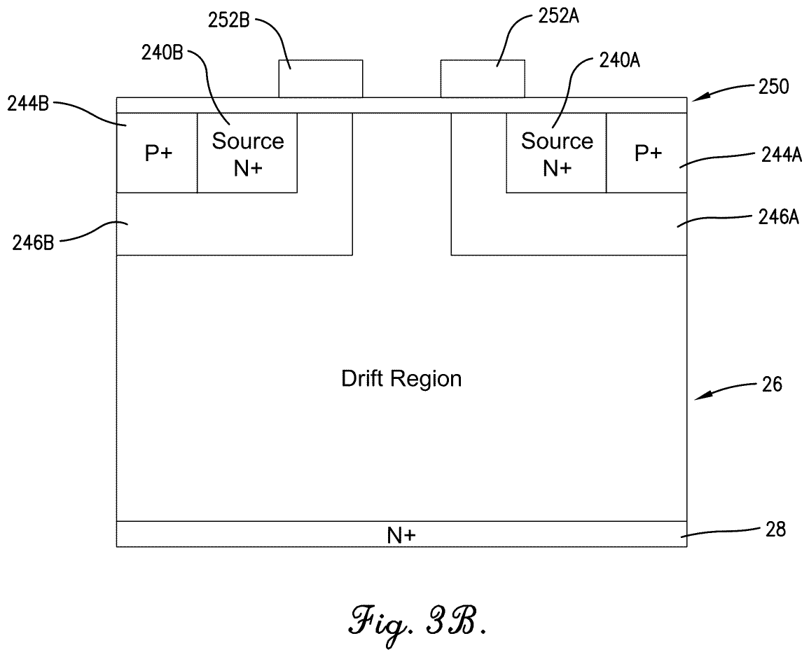

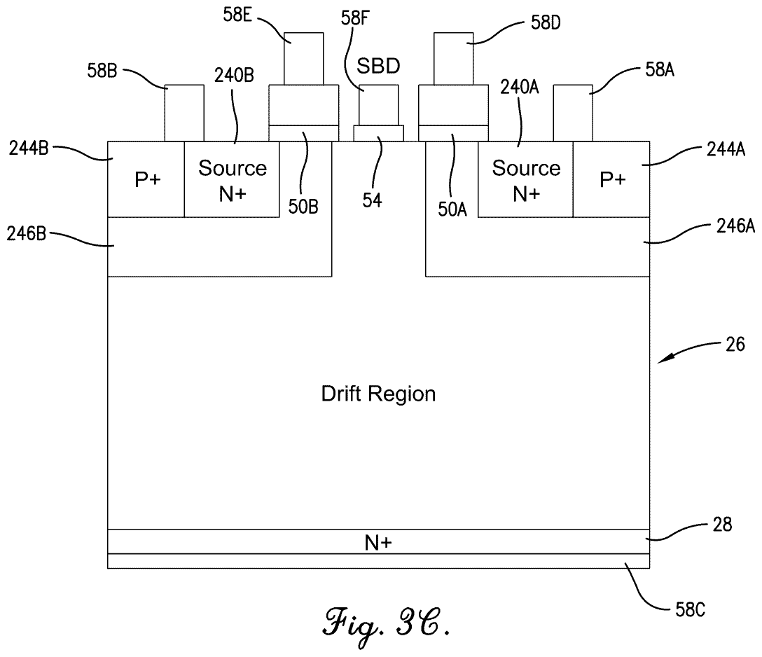

Referring to FIG. 2, an example of a method 120 of making an apparatus with an integrated planar MOSFET and an integrated planar SBD may include the following operations. References are also made to FIGS. 3A-C showing the results of certain of the operations of the method 120, and to FIG. 1 and the example apparatus 20 described above which may be made using the method 120. As discussed above, the first and second MOSFET sides 30A, 30B may be mirror-images or “flipped” versions of each other. The first and second MOSFET sides 30A, 30B may otherwise be substantially similar or identical and created simultaneously.

The doped substrate material 28 may be provided, as shown in 122 and seen in FIG. 3A. The doped substrate material 28 may be a single, physically continuous structure that is shared by the first and second MOSFET sides 30A, 30B and the integrated SBD 34. Thus, the first and second MOSFET sides 30A, 30B may include respective first and second portions of the doped substrate material 28. The doped substrate material 28 may be constructed from or include an N+ doped substrate material.

The volume of semiconductor material 26 may be grown or otherwise deposited on the doped substrate material 28, as shown in 124 and seen in FIG. 3A. The volume of semiconductor material 26 may include a first end, a second end, a first side, and a second side. The doped substrate material 28 may be located at the second end of the volume of semiconductor material 26, the first and second MOSFET sides 30A, 30B may be located at respective first and second sides of the volume of semiconductor material 26, and a region of the volume of semiconductor material 26 located between the first and second MOSFET sides 30A, 30B may provide the JFET neck region 32. The volume of semiconductor material 26 may be constructed from or include an N-type epitaxial semiconductor material.

The first and second MOSFET sides 30A, 30B may be simultaneously constructed, as seen in FIGS. 3A-3C. The integrated planar MOSFET 30 may be a SiC MOSFET. The first and second MOSFET sides 30A, 30B may include respective first and second regions or subvolumes of the volume of semiconductor material 26. Thus, the volume of semiconductor material 26 may be a single, physically continuous structure that is shared by the first and second MOSFET sides 30A, 30B and the integrated SBD 34.

The first and second MOSFET sides 30A, 30B may further include respective first and second instances of various structures and materials. The first and second instances of the various structures and materials may be implanted (using, e.g., an ion implanter), deposited, or otherwise provided using a suitable technique in or on the respective subvolumes of the volume semiconductor material 26. These structures and materials and their sizes and positions may vary, but may generally include the following. First and second structures of P+ material 246A, 246B for the respective first and second P-wells 46A, 46B may be implanted or otherwise provided in the respective subvolumes at the first end of the volume of semiconductor material 26, as shown in 126 and seen in FIG. 3A. First and second structures of N+ material 240A, 240B for the respective first and second sources 40A, 40B may be implanted or otherwise provided in the respective subvolumes of the volume of semiconductor material 26 at the first end, over and adjacent to the respective first and second structures of P+ material and generally opposite the first and second drains 42A, 42B provided by the respective portions of the doped substrate material 28, as shown in 128 and seen in FIG. 3A. Third and fourth structures of P+ material 244A, 244B for the respective first and second body contacts 44A, 44B may be implanted or otherwise provided adjacent to the respective first and second sources 40A, 40B, such that each body contact 44A, 44B is located on an opposite side of the respective source 40A, 40B from the respective P-wells 46A, 46B, as shown in 130 and seen in FIG. 3A. It will be understood that the first and second channels 48A, 48B may be provided by respective first and second regions of the respective subvolumes of the volume of semiconductor material 26 between the respective structures of N+ material 240A, 240B of the first and second sources 40A, 40B and the doped substrate material 28 of the respective first and second drains 42A, 42B. The majority charge carriers may move and the electrical current may flow through the channels 48A 48B.

A single layer of dielectric material 250, or gate oxide (e.g., silicon dioxide (SiO2)), may be deposited or other provided over the first end of the volume of semiconductor material 26, as shown in 132 and seen in FIG. 3B. First and second structures of the doped (e.g., P-type) polysilicon material 252A, 252B for the first and second gates 52A, 52B may be deposited or otherwise provided over portions of the single layer of dielectric material 250, as shown in 134 and seen in FIG. 3B. As seen in FIG. 1, no polysilicon material is provided over the center portion of the JFET neck region 32 between the first and second MOSFET sides 30A, 30B. Thus, the first and second gates 52A, 52B may be located on either side of the JFET neck region 32. The single layer of dielectric material 250 may be etched or otherwise processed to remove the dielectric material 250 from the first end of the volume of semiconductor material 26 except under the first and second structures of the doped polysilicon material 252A, 252B, as shown in 136 and seen in FIG. 3C. This results in the first and second layers of dielectric material 50A, 50B remaining over a portion of respective sides of the JFET neck region 32, at least partially over the first and second structure of P+ material of the respective first and second P-wells 46A, 46B, and at least partially over the first and second structures of N+ material 240A, 240B of the respective first and second sources 40A, 40B. As seen in FIG. 1, none of the dielectric material remains over a center portion of the JFET neck region 32 between the first and second MOSFET sides 30A, 30B.

The Schottky material 54 for the SBD 34 may be deposited or otherwise provided over the center portion of the JFET neck region 32 between the first and second MOSFET sides 30A, 30B, as shown in 138 and seen in FIG. 3C. The Schottky material 54 may be a metal such as titanium, molybdenum, platinum, chromium, tungsten, aluminum, or combinations thereof.

Electrical terminals 58A-F may be added to facilitate applying appropriate electrical voltages, as discussed above, as shown in 140 and seen in FIG. 3C. More specifically, first and second electrical terminals 58A, 58B, may be added to the respective first and second sources 40A, 40B, a single third electrical terminal 58C may be added that spans the first and second drains 42A, 42B, fourth and fifth electrical terminals 58D, 58E may be added to the respective first and second gates 52A, 52B, and a sixth electrical terminal 58F may be added to the integrated SBD 34.

Additional processing may be performed as desired.

While the present disclosure has been described herein with respect to certain illustrated examples, those of ordinary skill in the art will recognize and appreciate that the present disclosure is not so limited. Rather, many additions, deletions, and modifications to the illustrated and described examples may be made without departing from the scope of the disclosure as hereinafter claimed along with their legal equivalents. In addition, features from one example may be combined with features of another example while still being encompassed within the scope of the disclosure as contemplated by the inventors.

For example, although described herein with regard or in relation to one or more particular kinds of electronic devices (e.g., junction field-effect transistor, metal oxide semiconductor field-effect transistor), the technology may be more broadly applicable to one or more other kinds of electronic devices as well. Further, one with ordinary skill in the art will recognize that the technology described herein may, when applicable, be implemented in enhancement mode or depletion mode. Additionally, the technology described herein may, when applicable, be implemented as an N-channel or P-channel device, wherein, in general, regions that are N-doped or P-doped in N-channel implementations may be, respectively, P-doped or N-doped in P-channel implementations. Additionally, the various example materials identified herein may, in some aspects, be replaced or supplemented with substantially any other suitable material. For example, gate material may include polysilicon, a metal or alloy of metals, or other suitable material; gate oxide or dielectric may include silicon dioxide, aluminum dioxide, hafnium dioxide, silicon nitride, or other suitable material; and semiconductor material may include silicon carbide, gallium nitride, zinc oxide, or other suitable material.

Additionally, in general, unless otherwise specified or unless one with ordinary skill in the art would understand otherwise, doping concentrations for contact implants may be approximately between 10\hat{ }18 and 1×10\hat{ }22; doping concentrations for channel and threshold forming implants may be approximately between 10\hat{ }16 and 10\hat{ }17; doping concentrations for shielding implants may be approximately between 10\hat{ }17 and 10\hat{ }19; and doping concentrations for conductivity improvement implants (e.g., N-doping in the junction field-effect transistor neck region of a metal oxide semiconductor field-effect transistor) may be approximately between 10\hat{ }16 and 10\hat{ }17. Relatedly, a structure or region may contain two or more different doping doses. For example, one with ordinary skill in the art will recognize that some P-wells may contain a lower dose P-well portion and a higher dose unclamped inductive switching portion.

1. An apparatus comprising:
a volume of semiconductor material including a first end, a second end, a first side, and a second side;
an integrated planar metal oxide semiconductor field-effect transistor including a first transistor side located at the first side of the volume of semiconductor material, the first transistor side including—
a first P-well located at the first end of the volume of semiconductor material, and
a first gate including—
a layer of dielectric material over at least a portion of the first P-well, and
a first layer of doped polysilicon over the first layer of dielectric material;
a junction field effect transistor neck region of the volume of semiconductor material located adjacent to the first transistor side; and
an integrated planar Schottky barrier diode including a Schottky material located at the first end of the volume of semiconductor material over at least a portion of the junction field-effect transistor neck region adjacent to and spaced apart from the first transistor side.

2. The apparatus of claim 1, wherein the first transistor side further includes—
a first source including a first N+ material located above and adjacent to the first P-well;
a first body including a first P+ material located adjacent to the first source opposite the first P-well;
a first drain including an N+ substrate material located at the second end of the volume of semiconductor material; and
a first channel through the volume of semiconductor between the first source and the first drain.

3. The apparatus of claim 2, wherein the first layer of dielectric material extends over at least a portion of the first source and a first portion of the junction field-effect transistor neck region.

4. The apparatus of claim 1, wherein the integrated planar metal oxide semiconductor field-effect transistor further includes a second transistor side located at the second side of the volume of semiconductor material, wherein the junction field-effect transistor neck region is located between the first and second transistor sides, the second transistor side including—
a second P-well located at the first end of the volume of semiconductor material; and
a second gate including—
a second layer of dielectric material located over at least a portion of the second P-well, and
a second layer of doped polysilicon over the second layer of dielectric material.

5. The apparatus of claim 4, wherein the second transistor side further includes—
a second source including a second N+ material located above and adjacent to the second P-well;
a second body including a second P+ material located adjacent to the second source opposite the second P-well;
a second drain including an N+ substrate material located at the second end of the volume of semiconductor material; and
a second channel through the volume of semiconductor between the second source and the second drain.

6. The apparatus of claim 5, wherein the second layer of dielectric material extends over at least a portion of the second source and a second portion of the junction field-effect transistor neck region.

7. The apparatus of claim 1, wherein the Schottky material is selected from the group consisting of: titanium, molybdenum, platinum, chromium, tungsten, aluminum, and combinations thereof.

8. An apparatus comprising:
a volume of semiconductor material including a first end, a second end, a first side, and a second side;
an integrated planar metal oxide semiconductor field-effect transistor including—
a first transistor side located at the first side of the volume of semiconductor material, the first transistor side including—
a first well located at the first end of the volume of semiconductor material, and
a first gate over at least a portion of the first well, and
a second transistor side located at the second side of the volume of semiconductor material, the second transistor side including—
a second well located at the first end of the volume of semiconductor material, and
a second gate over at least a portion of the second well; and
a junction field effect transistor neck region of the volume of semiconductor material located between the first transistor side and the second transistor side; and
an integrated planar Schottky barrier diode including a Schottky material located at the first end of the volume of semiconductor material over at least a portion of the junction field-effect transistor neck region between and spaced apart from the first and second transistor sides.

9. The apparatus of claim 8, wherein the first gate includes a first layer of dielectric material and a first later of doped polysilicon over the first layer of dielectric material, and the second gate includes a second layer of dielectric material and a second later of doped polysilicon over the second layer of dielectric material.

10. The apparatus of claim 9, wherein the first well is formed of a first P material, and the first transistor side further includes—
a first source including a first N+ material located above and adjacent to the first well;
a first body including a first P+ material located adjacent to the first source opposite the first well;
a first drain including an N+ substrate material located at the second end of the volume of semiconductor material; and
a first channel through the volume of semiconductor between the first source and the first drain.

11. The apparatus of claim 10, wherein the second well is formed of a second P material and the second transistor side further includes—
a second source including a second N+ material located above and adjacent to the second well;
a second body including a second P+ material located adjacent to the second source opposite the second well;
a second drain including the N+ substrate material located at the second end of the volume of semiconductor material; and
a second channel through the volume of semiconductor between the second source and the second drain.

12. The apparatus of claim 11, wherein the first layer of dielectric material extends over at least a portion of the first source and a first portion of the junction field-effect transistor neck region, and the second layer of dielectric material extends over at least a portion of the second source and a second portion of the junction field-effect transistor neck region.

13. The apparatus of claim 12, wherein the Schottky material is a metal selected from the group consisting of: titanium, molybdenum, platinum, chromium, tungsten, aluminum, and combinations thereof.

14. The apparatus of claim 8, wherein—
the first transistor side includes a first source located above and adjacent the first well;
the second transistor side includes a second source located above and adjacent the second well;
the first gate extending over at least a portion of the first source and a first portion of the junction field-effect transistor neck region; and
the second gate extending over at least a portion of the second source a second portion of the junction field-effect transistor neck region.

15. The apparatus of claim 14, wherein the first gate includes a first layer of dielectric material and a first later of doped polysilicon over the first layer of dielectric material, and the second gate includes a second layer of dielectric material and a second later of doped polysilicon over the second layer of dielectric material.

16. The apparatus of claim 8, wherein the Schottky material is a metal selected from the group consisting of: titanium, molybdenum, platinum, chromium, tungsten, aluminum, and combinations thereof.

17. A method comprising:
growing a volume of semiconductor material including a first end, a second end, a first side, and a second side, and including a junction field effect transistor neck region;
forming a first transistor side of an integrated planar metal oxide semiconductor field-effect transistor at the first side of the volume of semiconductor material and adjacent to the junction field effect transistor neck region, wherein the operation of forming the first transistor side includes—
implanting a first P-well at the first end of the volume of semiconductor material, and
forming a first gate, wherein the operation of forming the first gate includes—
depositing a first layer of dielectric material over at least a portion of the first P-well, and
depositing a first layer of doped polysilicon over the first layer of dielectric material; and
making an integrated planar Schottky barrier diode including adding a Schottky material at the first end of the volume of semiconductor material over at least a portion of the junction field-effect transistor neck region adjacent and spaced apart from the first transistor side.

18. The method of claim 17, further comprising—
forming a second transistor side of the integrated planar metal oxide semiconductor at the second side of the volume of semiconductor material, wherein the operation of forming the second transistor side includes—
implanting a second P-well at the first end of the volume of semiconductor material, and
forming a second gate, wherein the operation of forming the second gate includes—depositing a second layer of dielectric material over at least a portion of the second P-well, and depositing a second layer of doped polysilicon over the second layer of dielectric material.

19. The method of claim 18,
the operation of forming the first transistor side further including—
implanting a first N+ material for a first source above and adjacent to the first P-well,
implanting a first P+ material for a first body adjacent to the first source opposite the first P-well, and
providing an N+ substrate material for a first drain at the second end of the volume of semiconductor material,
wherein the volume of semiconductor between the first source and the first drain provides a first channel; and
the operation of forming the second transistor side further including—
implanting a second N+ material for a second source above and adjacent to the second P-well, and
implanting a second P+ material for a second body adjacent to the second source opposite the second P-well,
wherein the N+ substrate material provides a second drain at the second end of the volume of semiconductor material,
wherein the volume of semiconductor between the first source and the first drain provides a second channel.

20. The method of claim 19, the operation of forming the first gate including extending the first layer of dielectric material over at least a portion of the first source and a first portion of the junction field-effect transistor neck region, and the operation of forming the second gate including extending the second layer of dielectric material over at least a portion of the second source and a second portion of the junction field-effect transistor neck region.
